(19) United States
(12) Patent Application Publication
(10) Pub. No.: US 2026/0202862 A1
(43) Pub. Date: Jul. 16, 2026

(54) FAN SYSTEM

(71) Applicant: Global Mixed-mode Technology Inc., Hsin-chu (TW)

(72) Inventor: Rong-Chin Lee, Pingtung County (TW)

(73) Assignee: Global Mixed-mode Technology Inc., Hsin-Chu (TW)

(21) Appl. No.: 19/021,115

(22) Filed: Jan. 14, 2025

(51) Int. Cl. G05D 7/06; H03K 3/017

(52) U.S. Cl. CPC G05D 7/0623; G05D 7/0682; H03K 3/017

(57) ABSTRACT

A fan system is applied to a single fan mechanism or a multi-fan mechanism. The fan system comprises a controller and a first fan. The controller is configured to output a command signal to the first fan based on an instruction set. The command signal is configured to control a rotation speed of the first fan. The first fan informs the controller of first rotation speed information according to the instruction set. The fan system may be configured to reduce the wire cost.

### BACKGROUND OF THE INVENTION

### 1. Field of the Invention

The present invention relates to a fan system, and more particularly, to a fan system which is applied to a single-fan mechanism or a multi-fan mechanism.

### 2. Description of the Prior Art

Conventionally, a controller controls a rotation speed of a fan based a pulse width modulation mode. However, when the controller controls a single fan or a plurality of fans based on the pulse width modulation mode, it results in a heavy burden on the controller. Moreover, when more and more fans are used in a system, traditional techniques increase the wire cost and cause the wire congestion issue.

Thus, a new fan system technology is needed to solve the above issues.

### SUMMARY OF THE INVENTION

According to a first embodiment of the present invention, a first fan system is provided. The first fan system comprises a controller and a first fan. The controller has a transmit terminal and a receive terminal, where the controller may be a host controller. The first fan has a first command terminal and a first rotation speed terminal. The controller may be configured to output a command signal to the first command terminal of the first fan via the transmit terminal based on an instruction set, where the command signal may be configured to control a rotation speed of the first fan. In addition, the first fan may inform the controller of first rotation speed information via the first rotation speed terminal according to the instruction set, where the controller may receive the first rotation speed information through the receive terminal. The first rotation speed information is related to the rotation speed of the first fan.

The first fan system may adopt a communication protocol mode. The controller may prepare to enter the communication protocol mode by maintaining the command signal at a low level for a duration greater than or equal to a first predetermined time or at a high level for a duration greater than or equal to a second predetermined time. For example, the first fan system may adopt a Universal Asynchronous Receiver Transmitter mode. That is, the instruction set may be related to the Universal Asynchronous Receiver Transmitter mode.

The command signal may include an M-bit value. The M-bit value may be used to control the rotation speed of the first fan, where M is a positive integer and is greater than or equal to 2. The designer may create a rotation speed instruction that includes the M-bit value, where the command signal may include the rotation speed instruction. The first rotation speed information may be an N-bit value, where N is a positive integer and is greater than or equal to 2. The designer may create a rotation speed information feedback instruction to instruct the first fan to report the first rotation speed information back to the controller, where the command signal may include the rotation speed information feedback instruction.

When the command signal includes a program instruction, the first fan may enter a program mode. The program mode may be used to control the rotation speed of the first fan. The first fan system may have a control mechanism that allows the controller to re-enter the program mode while in a crash state.

Additionally, a default mode of the first fan system may control the first fan based on a pulse width modulation waveform, where the command signal may include the pulse width modulation waveform. When the command signal includes the program instruction, the first fan system switches from the default mode to the program mode.

The fan system of the present invention may be applied to a single fan mechanism or a multi-fan mechanism. According to a second embodiment of the present invention, a second fan system is provided. The second fan system comprises the controller, the first fan, and a second fan. It should be noted that all the technical features of the aforementioned first fan system are applicable to the second fan system, and the present invention will not repeat these details here.

The second fan has a second command terminal and a second rotation speed terminal. The second fan system forms a closed loop among the controller, the first fan, and the second fan through a daisy-chaining mechanism, where the daisy-chaining mechanism may achieve the objectives of reducing the wire cost and avoiding the wire congestion. The daisy-chaining mechanism connects the controller and the first fan via the transmit terminal and the first command terminal, where the transmit terminal is coupled to the first command terminal. It also connects the first fan and the second fan via the first rotation speed terminal and the second command terminal, where the first rotation speed terminal is coupled to the second command terminal. Additionally, the daisy-chaining mechanism connects the second fan and the controller via the second rotation speed terminal and the receive terminal, where the second rotation speed terminal is coupled to the receive terminal.

The second fan system may operate in a pass-through mode or a non-pass-through mode. First, the controller outputs the command signal to the first fan. In the pass-through mode, the first fan may transmit the command signal to the second fan via the first rotation speed terminal. In the non-pass-through mode, the first fan may transmit first rotation speed information to the second fan via the first rotation speed terminal. Furthermore, the second fan may determine, based on the command signal, whether to output the first rotation speed information or second rotation speed information to the controller via the second rotation speed terminal. In other words, the second fan may transmit the first rotation speed information to the controller via the second rotation speed terminal. The second fan may also transmit the second rotation speed information to the controller via the second rotation speed terminal.

The command signal may include a numbering instruction. The numbering instruction may be used to assign a first number to the first fan and a second number to the second fan. The first fan may record the first number, and the second fan may record the second number. Accordingly, the controller may ensure that the issued command signal will not control the wrong fan. In addition, the controller may use an action instruction to make both the first fan and the second fan operate simultaneously, where the command signal may include the action instruction.

Through the technology of the instruction set, the fan system of the present invention may be applied to a building block fan system, enabling the single fan mechanism or the multi-fan mechanism. The first fan and the second fan may both be axial fans. Additionally, the first fan and the second fan may also both be centrifugal fans. The user may select the type of the fan according to the actual system application.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The above-mentioned and other objects, features, and advantages of the present invention will become apparent with reference to the following descriptions and accompanying drawings, wherein:

FIG. 1 is a block diagram of a first fan system according to a first embodiment of the present invention; and

FIG. 2 is a block diagram of a second fan system according to a second embodiment of the present invention.

### DETAILED DESCRIPTION

Preferred embodiments according to the present invention will be described in detail with reference to the drawings.

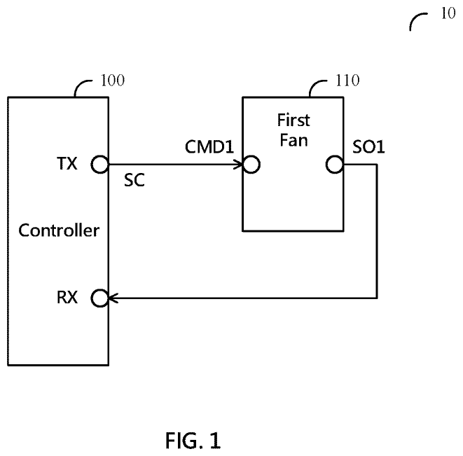

FIG. 1 is a block diagram of a first fan system 10 according to a first embodiment of the present invention, where the first fan system 10 comprises a controller 100 and a first fan 110. The controller 100 has a transmit terminal TX and a receive terminal RX, where the controller 100 may be a host controller. The first fan 110 has a first command terminal CMD1 and a first rotation speed terminal SO1. Unlike traditional pulse width modulation modes and duty cycle driving methods, the controller 100 may be configured to output a command signal SC to the first command terminal CMD1 of the first fan 110 via the transmit terminal TX based on an instruction set, where the command signal SC may be configured to control a rotation speed of the first fan 110. In addition, the first fan 110 may inform the controller 100 of first rotation speed information via the first rotation speed terminal SO1 according to the instruction set, where the controller 100 may receive the first rotation speed information through the receive terminal RX. The first rotation speed information is related to the rotation speed of the first fan 110. The controller 100 controls the operation of the first fan 110 based on the instruction set, thereby reducing the system burden.

To achieve the goal of reducing the system burden, the first fan system 10 may adopt a communication protocol mode, but the present invention is not limited thereto. The controller 100 may prepare to enter the communication protocol mode by maintaining the command signal SC at a low level for a duration greater than or equal to a first predetermined time or at a high level for a duration greater than or equal to a second predetermined time. For example, the first fan system 10 may adopt a Universal Asynchronous Receiver Transmitter (UART) mode. That is, the instruction set may be related to the Universal Asynchronous Receiver Transmitter mode. By utilizing the widely used Universal Asynchronous Receiver Transmitter mode, the designer may reduce development time and costs.

The command signal SC may include an M-bit value. The M-bit value may be used to control the rotation speed of the first fan 110, where M is a positive integer and is greater than or equal to 2. For example, M may be equal to 8. The designer may create a rotation speed instruction that includes the M-bit value, where the command signal SC may include the rotation speed instruction. In other words, the rotation speed control method of the present invention may differ from the conventional duty cycle driving method. The first rotation speed information may be an N-bit value, where N is a positive integer and is greater than or equal to 2. For example, N may be equal to 16. The designer may create a rotation speed information feedback instruction to instruct the first fan 110 to report the first rotation speed information back to the controller 100, where the command signal SC may include the rotation speed information feedback instruction.

When the command signal SC includes a program instruction, the first fan 110 may enter a program mode. The program mode may be used to control the rotation speed of the first fan 110. The first fan system 10 may have a control mechanism that allows the controller 100 to re-enter the program mode while in a crash state.

Additionally, a default mode of the first fan system 10 may operate without relying on the instruction set to control the first fan 110. For example, the default mode of the first fan system 10 may control the first fan 110 based on a pulse width modulation waveform, where the command signal SC may include the pulse width modulation waveform. When the command signal SC includes the program instruction, the first fan system 10 switches from the default mode to the program mode. It is noted that the designer may decide whether the default mode is necessary based on the actual system application.

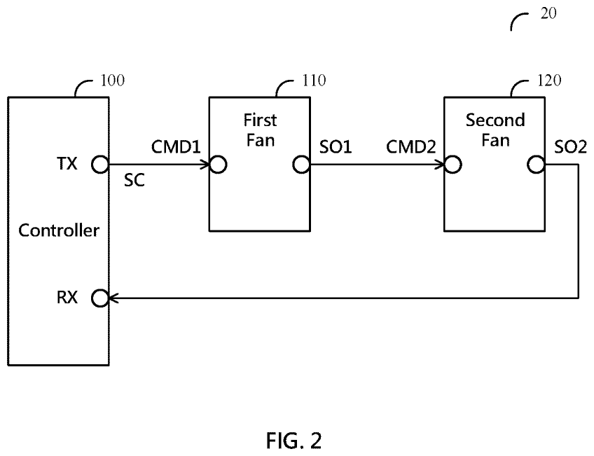

The fan system of the present invention may be applied to a single fan mechanism or a multi-fan mechanism, where FIG. 1 is an example block diagram of the single fan mechanism. In fact, the fan system of the present invention may daisy-chain O fans, where O is a positive integer and O is greater than or equal to 2. Thus, the fan system of the present invention may be configured to reduce the wire cost. For example, O may be equal to 2, 3, 4, 5, 6, 7, 8, 9, 10, 11, 12, 13, 14, 15, 16, or other positive integers greater than 16. FIG. 2 is an example block diagram of the multi-fan mechanism, where O is equal to 2. More specifically, FIG. 2 is a block diagram of a second fan system 20 according to a second embodiment of the present invention, where the second fan system 20 comprises the controller 100, the first fan 110, and a second fan 120. It should be noted that all the technical features of the aforementioned first fan system 10 are applicable to the second fan system 20, and the present invention will not repeat these details here.

The second fan 120 has a second command terminal CMD2 and a second rotation speed terminal SO2. As shown in FIG. 2, the second fan system 20 forms a closed loop among the controller 100, the first fan 110, and the second fan 120 through a daisy-chaining mechanism, where the daisy-chaining mechanism may achieve the objectives of reducing the wire cost and avoiding the wire congestion. The daisy-chaining mechanism connects the controller 100 and the first fan 110 via the transmit terminal TX and the first command terminal CMD1, where the transmit terminal TX is coupled to the first command terminal CMD1. It also connects the first fan 110 and the second fan 120 via the first rotation speed terminal SO1 and the second command terminal CMD2, where the first rotation speed terminal SO1 is coupled to the second command terminal CMD2. Additionally, the daisy-chaining mechanism connects the second fan 120 and the controller 100 via the second rotation speed terminal SO2 and the receive terminal RX, where the second rotation speed terminal SO2 is coupled to the receive terminal RX. It is noted that the designer may deduce the connection relationships for daisy-chaining O fans based on the logic of the daisy-chaining mechanism, where O is a positive integer and O is greater than 2. The present invention will not provide further examples in detail.

The second fan system 20 may operate in a pass-through mode or a non-pass-through mode. First, the controller 100 outputs the command signal SC to the first fan 110. In the pass-through mode, the first fan 110 may transmit the command signal SC to the second fan 120 via the first rotation speed terminal SO1. That is, the controller 100 may control the operation of the second fan 120 or receive feedback information from the second fan 120 via the first fan 110. In the non-pass-through mode, the first fan 110 may transmit first rotation speed information to the second fan 120 via the first rotation speed terminal SO1. The first rotation speed information is related to the rotation speed of the first fan 110. Furthermore, the second fan 120 may determine, based on the command signal SC, whether to output the first rotation speed information or second rotation speed information to the controller 100 via the second rotation speed terminal SO2. The second rotation speed information is related to a rotation speed of the second fan 120. In other words, the second fan 120 may transmit the first rotation speed information to the controller 100 via the second rotation speed terminal SO2. The second fan 120 may also transmit the second rotation speed information to the controller 100 via the second rotation speed terminal SO2.

The command signal SC may include a numbering instruction. The numbering instruction may be used to assign a first number to the first fan 110 and a second number to the second fan 120. The first fan 110 may record the first number, and the second fan 120 may record the second number. Accordingly, the controller 100 may ensure that the issued command signal SC will not control the wrong fan. However, if the placement of the first fan 110 and the second fan 120 has already been determined during the system design, the numbering instruction may not be necessary. In addition, the controller 100 may use an action instruction to make both the first fan 110 and the second fan 120 operate simultaneously, where the command signal SC may include the action instruction. By enabling simultaneous operation of the first fan 110 and the second fan 120, the second fan systems 20 may enhance cooling efficiency, reduce noise, and improve system stability.

In summary, the instruction set may include the rotation speed instruction, the rotation speed information feedback instruction, the program instruction, the numbering instruction, the action instruction, and others. The designer may add or remove instructions from the instruction set based on actual system requirements, and the present invention is not limited thereto. Through the technology of the instruction set, the fan system of the present invention may be applied to a building block fan system, enabling the single fan mechanism or the multi-fan mechanism. The first fan 110 and the second fan 120 may both be axial fans. Additionally, the first fan 110 and the second fan 120 may also both be centrifugal fans. The user may select the type of the fan according to the actual system application.

While the present invention has been described by the preferred embodiments, it is to be understood that the invention is not limited to the disclosed embodiments. On the contrary, it is intended to cover various modifications. Therefore, the scope of the appended claims should be accorded the broadest interpretation so as to encompass all such modifications.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A fan system, wherein the fan system is applied to a single fan mechanism or a multi-fan mechanism, and the fan system comprises:
a controller; and
a first fan, wherein the controller is configured to output a command signal to the first fan based on an instruction set, the command signal is configured to control a rotation speed of the first fan, and the first fan informs the controller of first rotation speed information according to the instruction set.

2. The fan system of claim 1, wherein when the command signal includes a program instruction, the first fan enters a program mode.

3. The fan system of claim 2, wherein the program mode is used to control the rotation speed of the first fan.

4. The fan system of claim 1, wherein a default mode of the fan system controls the first fan based on a pulse width modulation waveform.

5. The fan system of claim 4, wherein when the command signal includes a program instruction, the fan system switches from the default mode to a program mode.

6. The fan system of claim 1, wherein a default mode of the fan system operates without relying on the instruction set to control the first fan.

7. The fan system of claim 6, wherein when the command signal includes a program instruction, the fan system switches from the default mode to a program mode.

8. The fan system of claim 1, wherein the command signal includes an M-bit value, the M-bit value is used to control the rotation speed of the first fan, M is a positive integer, and M is greater than or equal to 2.

9. The fan system of claim 1, wherein the first rotation speed information is an N-bit value, N is a positive integer, and N is greater than or equal to 2.

10. The fan system of claim 1, wherein the fan system adopts a communication protocol mode.

11. The fan system of claim 1, wherein the fan system adopts a Universal Asynchronous Receiver Transmitter mode.

12. The fan system of claim 1, wherein the controller prepares to enter a communication protocol mode by maintaining the command signal at a low level for a duration greater than or equal to a first predetermined time or at a high level for a duration greater than or equal to a second predetermined time.

13. The fan system of claim 1, wherein the command signal includes a numbering instruction, and the numbering instruction is used to assign a first number to the first fan.

14. The fan system of claim 1, wherein the fan system has a control mechanism that allows the controller to re-enter a program mode while in a crash state.

15. The fan system of claim 1, wherein the controller uses an action instruction to make both the first fan and a second fan operate simultaneously.

16. The fan system of claim 1, wherein the fan system daisy-chains O fans, O is a positive integer, and O is greater than or equal to 2.

17. The fan system of claim 1, wherein the fan system is configured to reduce the wire cost.

18. The fan system of claim 1, wherein the first fan is an axial fan.

19. The fan system of claim 1, wherein the first fan is a centrifugal fan.

20. The fan system of claim 1, wherein the controller is a host controller.

21. The fan system of claim 1, wherein the fan system is applied to a building block fan system.

22. A fan system, wherein the fan system is applied to a multi-fan mechanism, and the fan system comprises:
a controller;
a first fan; and
a second fan, wherein the controller is configured to output a command signal to the first fan, and in a pass-through mode, the first fan transmits the command signal to the second fan via a first rotation speed terminal.

23. The fan system of claim 22, wherein in a non-pass-through mode, the first fan transmits first rotation speed information to the second fan via the first rotation speed terminal.

24. The fan system of claim 23, wherein the second fan transmits the first rotation speed information to the controller via a second rotation speed terminal.

25. The fan system of claim 22, wherein the second fan transmits second rotation speed information to the controller via a second rotation speed terminal.

26. The fan system of claim 22, wherein when the command signal includes a program instruction, the first fan enters a program mode.

27. The fan system of claim 22, wherein a default mode of the fan system controls the first fan based on a pulse width modulation waveform.

28. The fan system of claim 27, wherein when the command signal includes a program instruction, the fan system switches from the default mode to a program mode.

29. The fan system of claim 22, wherein the fan system adopts a communication protocol mode.

30. The fan system of claim 22, wherein the fan system adopts a Universal Asynchronous Receiver Transmitter mode.

31. The fan system of claim 22, wherein the controller prepares to enter a communication protocol mode by maintaining the command signal at a low level for a duration greater than or equal to a first predetermined time or at a high level for a duration greater than or equal to a second predetermined time.

32. The fan system of claim 22, wherein the command signal includes a numbering instruction, and the numbering instruction is used to assign a first number to the first fan and a second number to the second fan.

33. The fan system of claim 22, wherein the fan system has a control mechanism that allows the controller to re-enter a program mode while in a crash state.

34. The fan system of claim 22, wherein the controller uses an action instruction to make both the first fan and the second fan operate simultaneously.

35. The fan system of claim 22, wherein the fan system daisy-chains O fans, O is a positive integer, and O is greater than or equal to 2.

36. The fan system of claim 22, wherein the fan system is configured to reduce the wire cost.

37. The fan system of claim 22, wherein both the first fan and the second fan are axial fans.

38. The fan system of claim 22, wherein both the first fan and the second fan are centrifugal fans.

39. The fan system of claim 22, wherein the controller is a host controller.

40. The fan system of claim 22, wherein the fan system is applied to a building block fan system.

41. The fan system of claim 22, wherein the fan system forms a closed loop among the controller, the first fan, and the second fan.
